(19) United States
(12) Patent Application Publication
(10) Pub. No.: US 2023/0229839 A1
(43) Pub. Date: Jul. 20, 2023

(54) VERIFICATION PROCESSING DEVICE, VERIFICATION PROCESSING METHOD, AND PROGRAM

(71) Applicant: MITSUBISHI HEAVY INDUSTRIES ENGINEERING, LTD., Yokohama-shi, Kanagawa (JP)

(72) Inventors: Keita HIRAYAMA, Tokyo (JP); Kenji TAKAO, Tokyo (JP); Kenta MASUMORI, Yokohama-shi, Kanagawa (JP)

(21) Appl. No.: 17/928,739

(22) PCT Filed: Apr. 7, 2021
(86) PCT No.: PCT/JP2021/014748

§ 371 Date: Nov. 30, 2022

(30) Foreign Application Priority Data
Jun. 3, 2020 (JP) 2020-096792

(51) Int. Cl. G06F 30/367

(52) U.S. Cl. CPC G06F 30/367

(57) ABSTRACT

This verification processing device is provided with: an inspection unit that performs model inspection on an inspection target model including a plurality of elements; a selection unit that selects at least one of the plurality of elements included in a counterexample outputted as a result of the model inspection; and an exclusion history generation unit that generates exclusion history information indicating an exclusion frequency for each of the plurality of elements. The inspection unit further performs another model inspection on the inspection target model obtained by excluding the selected element. When another counterexample has been outputted as a result of another model inspection, the exclusion history generation unit increases the exclusion frequency of the selected element and updates the exclusion history information. The selection unit selects an element that is high in the exclusion frequency, on the basis of the exclusion history information.

### TECHNICAL FIELD

The present disclosure relates to a verification processing device, a verification processing method, and a non-transitory computer readable recording medium storing a program. The present application claims the benefit of priority based on Japanese Patent Application No. 2020-096792 filed on Jun. 3, 2020 in Japan, the content of which is incorporated herein by reference.

### BACKGROUND ART

PTL 1 discloses performing comprehensive verification of an operation logic of a data processing system using model checking.

### CITATION LIST

### Patent Literature

[PTL 1] Japanese Unexamined Patent Application Publication No. 2008-071135

### SUMMARY OF INVENTION

### Technical Problem

For example, in a case of verifying an operation logic of a relay circuit in the model checking, simple verification of a basic operation logic of the relay circuit is not sufficient, and the verification needs to be performed by considering defects that may occur in a signal line or a circuit element included in the relay circuit.

Considering the defects of the signal line or the circuit element (for example, a short circuit or an open circuit of the signal line or a failure of the circuit element) may occur simultaneously and asynchronously regardless of the basic operation logic of the relay circuit, not only a state transition that may occur during a basic operation but also all combinations of defects that may occur from each state during the basic operation need to be comprehensively verified in the model checking.

However, in such a case, even in a case where a counterexample including a combination of a plurality of defects that have occurred in each signal line and each circuit element included in the relay circuit is output, there is a possibility that the combination of the defects includes a defect that does not necessarily contribute to leading to an unsafe event (that is not critical).

That is, the model checking is comprehensive checking of a condition (pattern) that leads to an unsafe event by representing all possible states of a model to be checked using a logical expression based on a binary decision diagram (BDD) or the like, and a state transition that is not necessarily critical may be included in a process leading to the unsafe event. Thus, counterexample analysis has to be performed for the counterexample that may include a non-critical defect with respect to the unsafe event, and there is a heavy load required for a work of the counterexample analysis in the model checking.

An object of the present disclosure is to provide a verification processing device, a verification processing method, and a program that can reduce a load required for a work of counterexample analysis in model checking.

### Solution to Problem

According to an aspect of the present disclosure, a verification processing device includes a checking unit that performs model checking on a model to be checked including a plurality of elements, a selection unit that selects one or more of a plurality of elements included in a counterexample output as a result of the model checking, and an exclusion history generation unit that generates exclusion history information indicating an exclusion frequency for each of a plurality of elements, in which the checking unit further performs model re-checking on the model to be checked obtained by excluding the selected element, in a case where another counterexample is output as a result of the model re-checking, the exclusion history generation unit increases the exclusion frequency of the selected element and updates the exclusion history information, and the selection unit selects an element of which the exclusion frequency is high based on the exclusion history information.

In addition, according to another aspect of the present disclosure, a verification processing method includes a step of performing model checking on a model to be checked including a plurality of elements, a step of selecting one or more of a plurality of elements included in a counterexample output as a result of the model checking, a step of generating exclusion history information indicating an exclusion frequency for each of a plurality of elements, a step of performing model re-checking on the model to be checked obtained by excluding the selected element, and a step of increasing, in a case where another counterexample is output as a result of the model re-checking, the exclusion frequency of the selected element and updating the exclusion history information, in which in the selecting step, an element of which the exclusion frequency is high is selected based on the exclusion history information.

In addition, according to still another aspect of the present disclosure, a program causing a computer to execute a step of performing model checking on a model to be checked including a plurality of elements, a step of selecting one or more of a plurality of elements included in a counterexample output as a result of the model checking, a step of generating exclusion history information indicating an exclusion frequency for each of a plurality of elements, a step of performing model re-checking on the model to be checked obtained by excluding the selected element, and a step of increasing, in a case where another counterexample is output as a result of the model re-checking, the exclusion frequency of the selected element and updating the exclusion history information, in which in the selecting step, an element of which the exclusion frequency is high is selected based on the exclusion history information.

### Advantageous Effects of Invention

According to each aspect above, a load required for a work of counterexample analysis in model checking can be reduced.

### BRIEF DESCRIPTION OF DRAWINGS

FIG. 1 is a diagram illustrating an overall configuration of a verification processing device according to at least one embodiment of the present disclosure.

FIG. 2 is a diagram illustrating a functional configuration of a CPU of the verification processing device according to at least one embodiment of the present disclosure.

FIG. 3 is a diagram illustrating an example of a model to be checked according to at least one embodiment of the present disclosure.

FIG. 4 is a diagram illustrating a processing flow of the verification processing device according to at least one embodiment of the present disclosure.

FIG. 5 is a diagram illustrating a process of updating exclusion history information by the verification processing device according to at least one embodiment of the present disclosure.

FIG. 6 is a diagram illustrating an example of the exclusion history information according to at least one embodiment of the present disclosure.

FIG. 7 is a diagram illustrating a processing flow of the verification processing device according to at least one embodiment of the present disclosure.

FIG. 8 is a diagram illustrating a processing flow of the verification processing device according to at least one embodiment of the present disclosure.

FIG. 9 is a diagram illustrating a processing flow of the verification processing device according to at least one embodiment of the present disclosure.

FIG. 10 is a diagram illustrating a processing flow of the verification processing device according to at least one embodiment of the present disclosure.

FIG. 11 is a diagram illustrating a functional configuration of the CPU of the verification processing device according to at least one embodiment of the present disclosure.

FIG. 12 is a diagram illustrating a content of a process of a threshold value decision unit according to at least one embodiment of the present disclosure.

### DESCRIPTION OF EMBODIMENTS

### First Embodiment

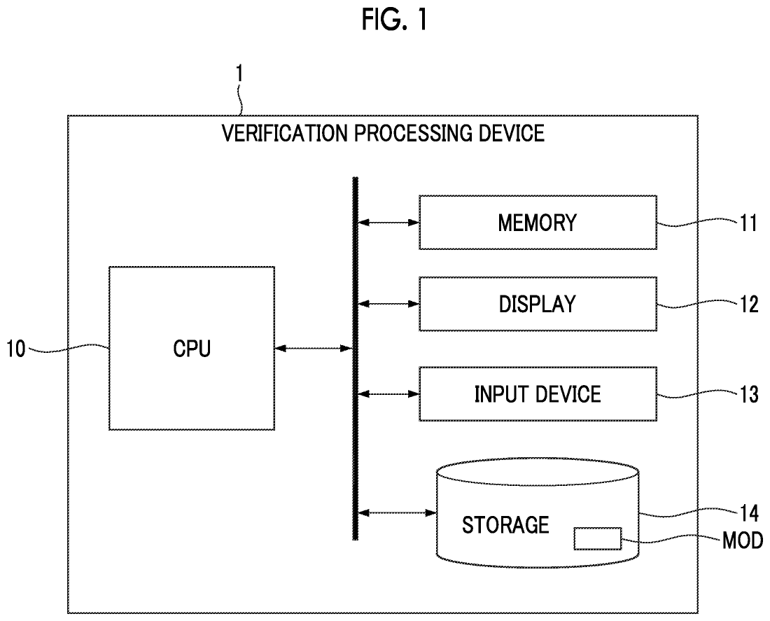

Hereinafter, a verification processing device according to a first embodiment will be described with reference to FIG. 1 to FIG. 10.

(Configuration of Verification Processing Device)

FIG. 1 is a diagram illustrating a configuration of the verification processing device according to the first embodiment.

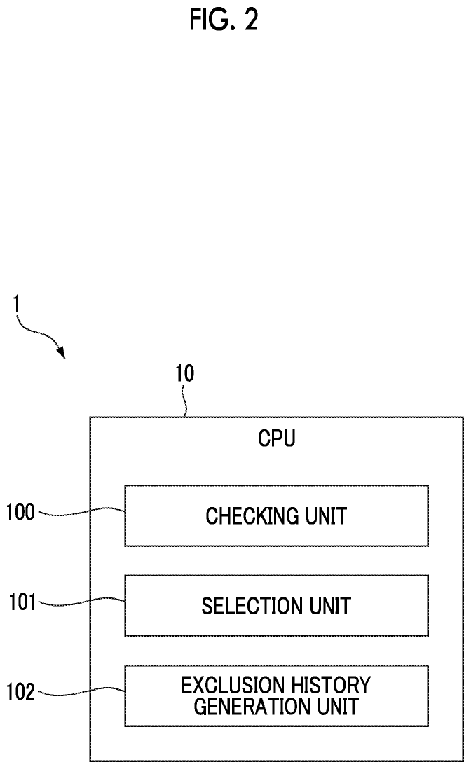

FIG. 2 is a diagram illustrating a functional configuration of a CPU of the verification processing device according to the first embodiment.

As illustrated in FIG. 1, a verification processing device 1 includes a CPU 10, a memory 11, a display 12, an input device 13, and a storage 14 and is configured as a general computer.

The memory 11 is a so-called main storage device, in which instructions and data for operating the CPU 10 based on a program are loaded.

The display 12 is a display device on which information is visually recognizably displayed, and may be, for example, a liquid crystal display or an organic EL display.

The input device 13 is an input device that receives an operation of a user of the verification processing device 1, and may be, for example, a general mouse, a keyboard, or a touch sensor.

The storage 14 is a so-called auxiliary storage device and may be, for example, a hard disk drive (HDD) or a solid state drive (SSD). For example, a model to be checked MOD that indicates a relay circuit as an object to be checked is recorded in the storage 14.

The CPU 10 is a processor that controls an overall operation of the verification processing device 1. As illustrated in FIG. 2, the CPU 10 according to the present embodiment functions as a checking unit 100, a selection unit 101, and an exclusion history generation unit 102.

The checking unit 100 performs (executes) model checking on the model to be checked MOD. The model checking performed here is comprehensive checking of a condition (pattern) that leads to an unsafe event by representing all possible states of the model to be checked using a logical expression based on a binary decision diagram (BDD) or the like. An algorithm of the model checking performed in the present embodiment may be a generally well-known algorithm.

The model to be checked MOD is information in which an operation logic of a system (for example, a railroad security system) as the object to be checked is defined. In the model checking, comprehensive operation verification of the system is performed in accordance with the operation logic defined here.

In addition, the unsafe event is a state defined as a state to which the system as the object to be checked is not to transition in any case. For example, in the railroad security system, a state “emergency brake does not work during an automatic driving control of a vehicle” or a state “crossing barrier is not lowered even in a case where a vehicle is traveling through a railroad crossing” is defined as the unsafe event.

The selection unit 101 selects one element from elements of which states have changed in a process leading to the unsafe event, based on a result of the model checking performed by the checking unit 100. The “element” is the minimum unit for defining the operation logic and the state of the model to be checked MOD, and is, for example, a signal line or a circuit element mounted on the relay circuit of the security system. As will be described later, the “element” includes not only an element that simulates an operation of the signal line or the circuit element mounted on the real relay circuit but also a virtual element defined for simulating an operation of the relay circuit when a defect occurs.

The selection unit 101 according to the present embodiment selects an element of which an exclusion frequency (exclusion history value) is relatively high based on exclusion history information (described later).

The exclusion history generation unit 102 generates the exclusion history information indicating the exclusion frequency for each of a plurality of the elements. In a case where a counterexample is output again as a result of performing the model checking again on the model to be checked MOD obtained by excluding the element selected by the selection unit 101 (that is, in a case where the counterexample is not eliminated even after the element is excluded), the exclusion history generation unit 102 increases the exclusion frequency of the element selected by the selection unit 101 and updates the exclusion history information.

(Example of Model to be Checked)

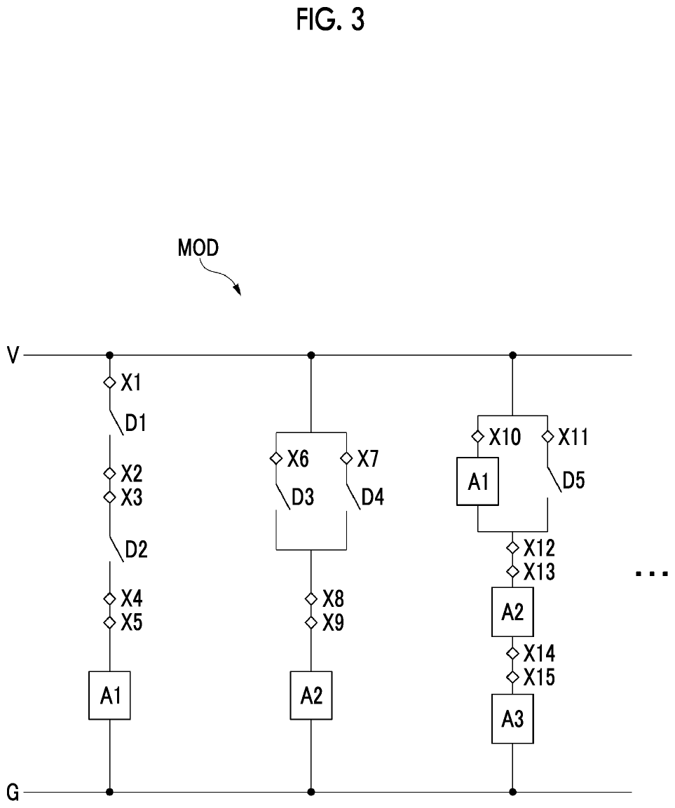

FIG. 3 is a diagram illustrating an example of the model to be checked according to the first embodiment.

As an example, the model to be checked MOD illustrated in FIG. 3 simulates the operation logic of the relay circuit constituting the railroad security system.

A wire V and a wire G illustrated in FIG. 3 are a power supply wire and a ground wire (ground), respectively. In addition, elements A1, A2, are relay switches and transition to an OFF state or an ON state in accordance with electrical conduction (0 (FALSE)=OFF/1 (TRUE)=ON). In addition, elements D1, D2, are manual switches and transition to the OFF state or the ON state by an operation of a person (0=OFF/1=ON).

Elements X1, X2, . . . are virtual elements defined for reproducing defects (an open circuit and a short circuit) that may occur in each signal line. For example, the element X1 is defined on a signal line connecting the wire V (power supply wire) to the element D1 (manual switch). The element X1 reproduces “occurrence of an open circuit” as one of defects in the signal line (0=open circuit/1=non-open circuit). In addition, the two elements X2 and X3 are defined on a signal line connecting the element D1 to the element D2 (manual switches). The element X2 reproduces “occurrence of an open circuit” in the signal line (0=open circuit/1=non-open circuit), and the element X3 reproduces “occurrence of a short circuit with the power supply line” in the signal line (0=non-short circuit/1=short circuit).

Similarly, the two elements X4 and X5 are defined on a signal line connecting the element D2 to the element A1 (relay switch). The element X4 reproduces “occurrence of an open circuit” in the signal line (0=open circuit/1=non-open circuit”, and the element X5 reproduces “occurrence of a short circuit with the power supply line” in the signal line (0=non-short circuit/1=short circuit).

The actual model to be checked MOD is described using a logical expression (language). For example, the element A1 (relay switch) is described as in Expression (1) by considering not only the manual switches D1 and D2 but also the defects (an open circuit and a short circuit) that may occur in each signal line.

A1=(X1 & D1 & X2 & D2 & X4) or (X3 & D2 & X4) or (X5) (1)

Other elements are also described using similar logical expressions.

The elements D1, D2, . . . that are manual switches are elements that have state transitions in accordance with an operation of a person. Thus, in the model checking, the elements D1, D2, . . . are defined such that simultaneous and asynchronous state transitions may occur at any timing like the elements X1, X2, . . . for defining the occurrence of the defects.

As will be described later, the model to be checked MOD is configured over a plurality of design drawings. The design drawings are mainly created separately for each function (for example, a design drawing for a brake of a vehicle and a design drawing for air conditioning).

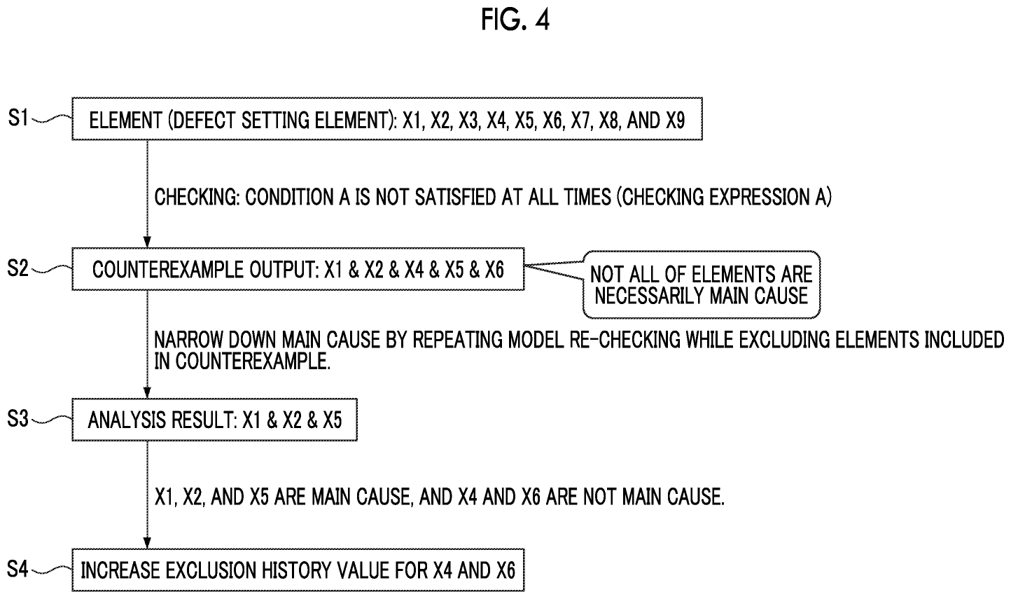

(Flow of Checking and Result Analysis) FIG. 4 is a diagram illustrating a processing flow of the verification processing device according to the first embodiment.

The processing flow illustrated in FIG. 4 illustrates a general flow of the model checking and result analysis using the verification processing device 1.

First, an element (defect setting element) in which the defects occur is set, and the model to be checked MOD is constructed (step S1). In the example illustrated in FIG. 4, the element X1 to the element X9 are set as the defect setting elements. A condition A (hereinafter, referred to as a “checking expression A”) indicating the unsafe event is set, and the model checking is performed.

As a result of the model checking, a counterexample (for example, X1 & X2 & X4 & X5 & X6) is output (step S2). As described above, in normal model checking, state transitions for the defect setting elements X1 to X9 are comprehensively checked in the process leading to the unsafe event (checking expression A), and a transition process leading to the checking expression A is occasionally output. Thus, the counterexample output here may include a state transition of the defect setting elements that is not necessarily a main cause (critical). That is, a result of the counterexample output is not necessarily an output of only a main cause of leading to the checking expression A.

Therefore, the verification processing device 1 excludes several elements included in the counterexample among the defect setting elements from the model to be checked MOD and performs model re-checking for the same checking expression A on the model to be checked MOD. For example, in a case where another counterexample is output as a result of the model checking performed on the model to be checked MOD obtained by excluding the defect setting element X6, a determination that the defect setting element X6 is not a main cause of the occurrence of the unsafe event (another element is the main cause) can be made. On the other hand, in a case where another counterexample is not output as a result of the model checking performed on the model to be checked MOD obtained by excluding the defect setting element X6, a determination that the defect setting element X6 is the main cause of the occurrence of the unsafe event can be made. Repeating this work narrows down the defect setting element that is the main cause.

As a result of the repeated model checking, the main cause is specified (result analysis) (step S3). The example in FIG. 4 is analyzed such that the defect setting element that is the main cause is X1, X2, and X5, and X4 and X6 are not the main cause.

The verification processing device 1 according to the present embodiment increases the exclusion history value for the defect setting elements X4 and X6 that are excluded as not being the main cause in the result analysis performed once, and updates the exclusion history information (step S4). This process of step S4 will be described later.

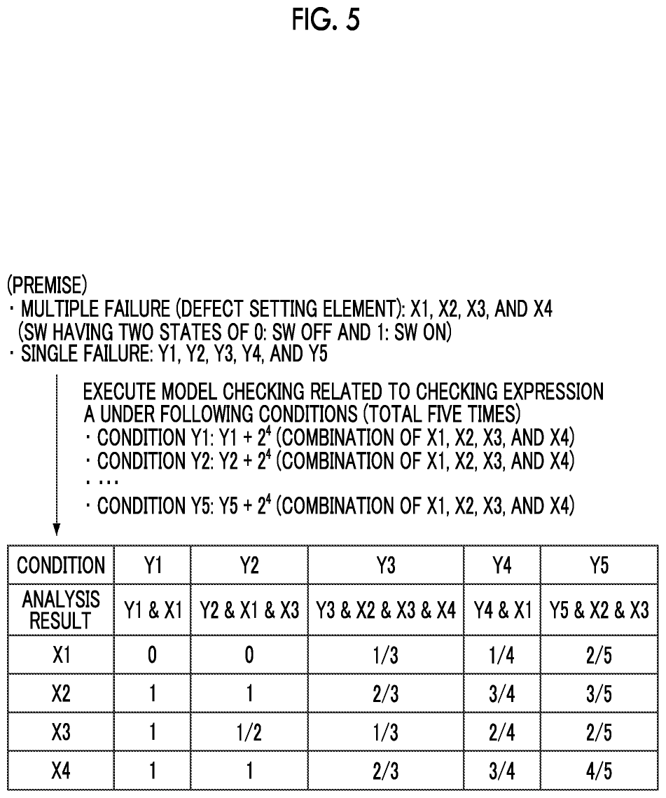

(Process of Updating Exclusion History Information) FIG. 5 is a diagram illustrating a process of updating the exclusion history information by the verification processing device according to the first embodiment.

First, a multiple failure and single failure will be described as a premise.

The multiple failure is a failure mode that may independently occur alone. All of the elements X1, X2, representing the short circuit, the open circuit, and the like as described using FIG. 3 are multiple failures. In the example illustrated in FIG. 5, the model to be checked MOD includes four types of multiple failures X1, X2, X3, and X4.

On the other hand, the single failure is a failure mode in which only one of a plurality of abnormal states may occur. For example, in a case where single failures Y1, Y2, Y3, Y4, and Y5 are set, only one of Y1 to Y5 occurs.

The actual model to be checked MOD is constructed to include the multiple failure and the single failure.

In a case of performing the model checking on the model to be checked MOD, the following procedure is performed.

First, which failure of the single failures Y1 to Y5 occurs (for example, Y1) is selected, and comprehensive checking of the multiple failures X1 to X4 is performed under a condition that the single failure Y1 occurs. After the model checking and the result analysis under an occurrence condition of the single failure Y1 are completed, the comprehensive checking of the multiple failures X1 to X4 is performed under a condition that the next single failure (for example, Y2) occurs. In such a manner, the verification processing device 1 according to the present embodiment performs the comprehensive checking a plurality of times and the result analysis for each occurrence condition of the single failure for one checking expression A.

The process of step S4 in FIG. 4 performed by the exclusion history generation unit 102 according to the present embodiment will be described in detail using the example illustrated in FIG. 5.

First, in a case where the final result analysis results in Y1 & X1 (that is, the multiple failure X1 is the main cause) as a result of the model checking performed under an occurrence condition of the single failure Y1, the exclusion history generation unit 102 adds an exclusion history value “1” for the multiple failures X2, X3, and X4 that are not the main cause (that is, excluded from the model to be checked MOD). This means that the number of times of exclusion is 1 in the result analysis performed once.

Next, in a case where the final result analysis results in Y2 & X1 & X3 (that is, the multiple failure X1 and the multiple failure X3 are the main cause) as a result of the model checking performed under an occurrence condition of the single failure Y2, the exclusion history generation unit 102 adds an exclusion history value “1” for the multiple failures X2 and X4 that are not the main cause (that is, excluded from the model to be checked MOD) and divides the whole number by 2 (number of times the result analysis is completed). Consequently, for example, the exclusion history value of the multiple failure X3 results in “½”. This means that the number of times of exclusion is 1 when the result analysis is completed twice.

Each time similar processes are performed for the single failures Y3, Y4, and Y5, the exclusion history generation unit 102 updates the exclusion history value for each of the multiple failures X1 to X5.

In such a manner, the exclusion history value indicates a frequency with which each element (multiple failures X1 to X5) is not the main cause in the model checking and the result analysis performed so far.

(Example of Exclusion History Information)

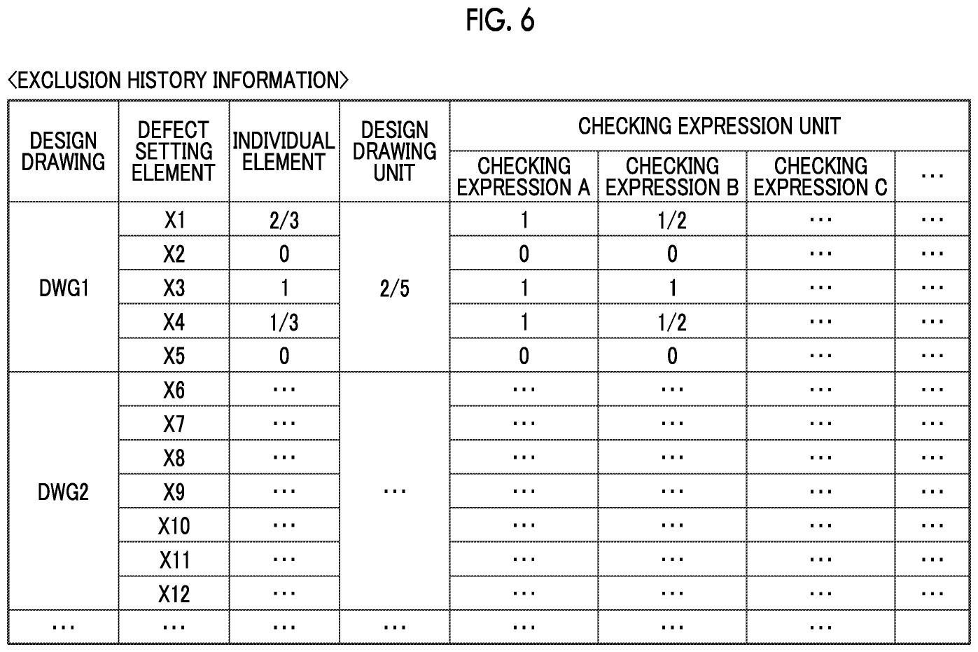

FIG. 6 is a diagram illustrating an example of the exclusion history information according to the first embodiment.

The exclusion history generation unit 102 according to the present embodiment creates the exclusion history information as illustrated in FIG. 6.

As illustrated in FIG. 6, the exclusion history information includes exclusion history values “individual element”, “drawing unit”, and “checking expression unit”.

The exclusion history value (hereinafter, referred to as an individual element exclusion history value) recorded in the field “individual element” is the exclusion history value of each element (defect setting element) accumulated through all result analysis performed so far.

Meanwhile, the exclusion history value (hereinafter, referred to as a checking expression unit exclusion history value) recorded in the field “checking expression unit”) is the exclusion history value of each element accumulated for each of checking expressions A, B, C, . . . .

In addition, the exclusion history value (hereinafter, referred to as a drawing unit exclusion history value) recorded in the field “drawing unit” is the exclusion history value calculated in design drawing units. Specifically, the drawing unit exclusion history value is an average value of individual element exclusion history values for each element included in one design drawing (that is, a value obtained by dividing a total of the individual element exclusion history values by the number of elements included in the design drawing). The drawing unit exclusion history value represents how the elements included in the design drawing are likely to be excluded as a whole in the drawing units.

(Processing Flow of Verification Processing Device)

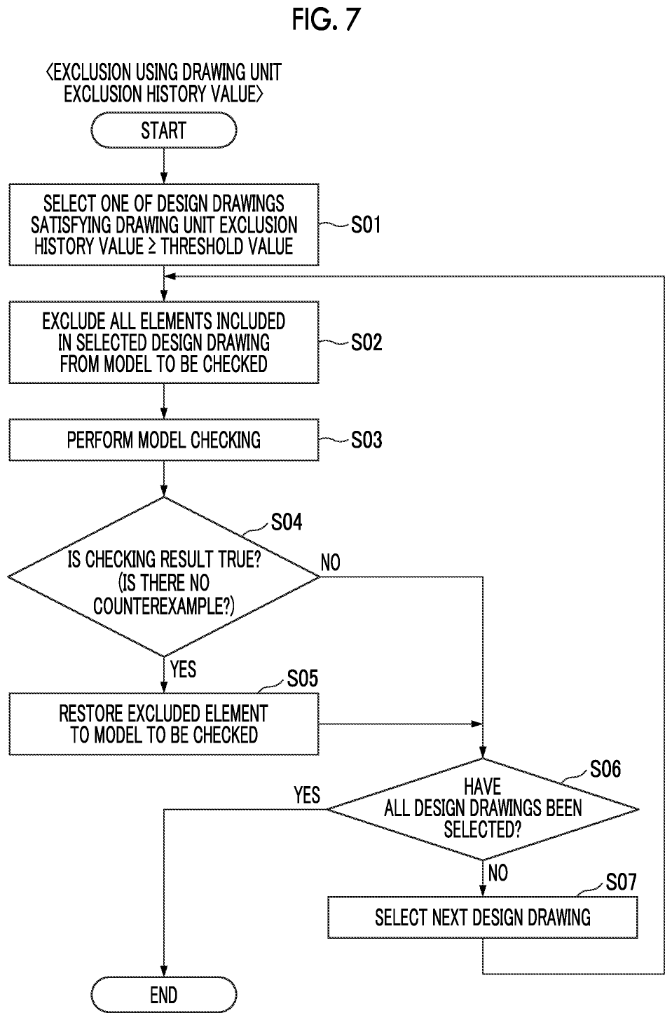

FIG. 7 to FIG. 10 are diagrams illustrating a processing flow of the verification processing device according to the first embodiment.

Hereinafter, a flow of process of narrowing down the main cause by the verification processing device 1 will be described in detail with reference to FIG. 7 to FIG. 10.

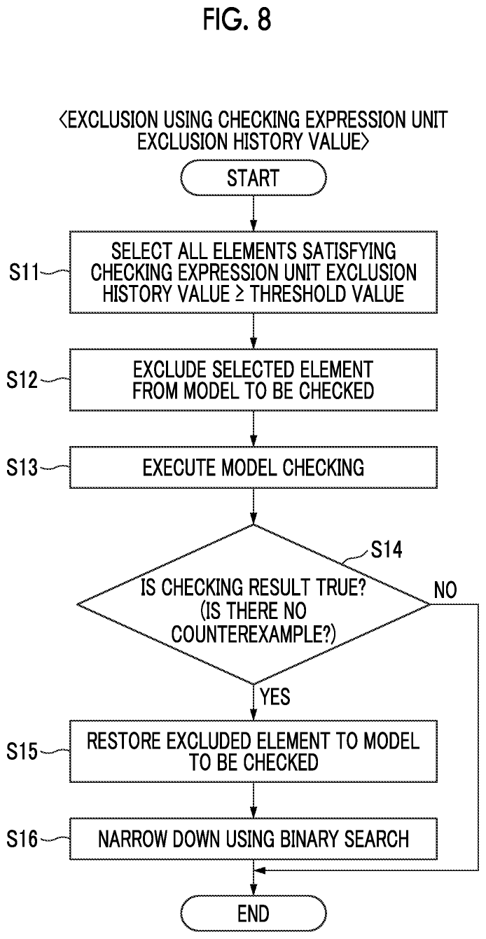

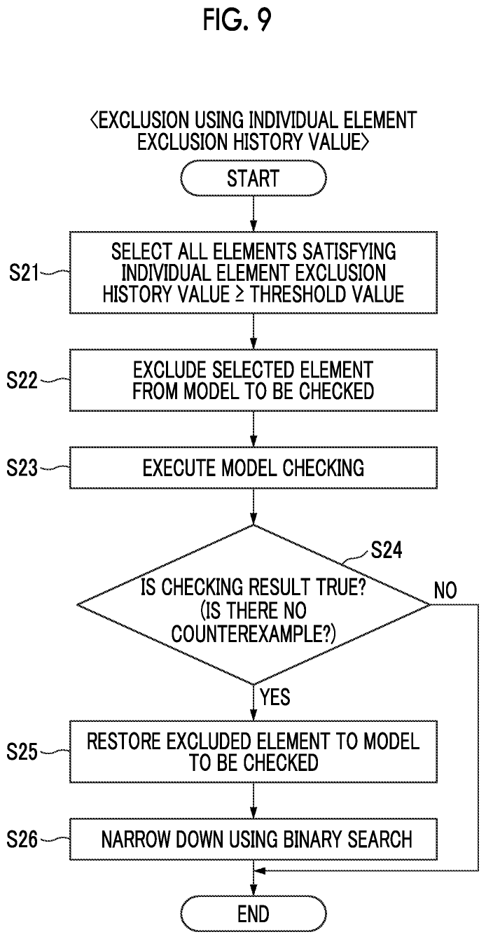

In narrowing down the main cause in a process from the counterexample output (step S2 in FIG. 4) to the result analysis (step S3 in FIG. 4), the verification processing device 1 according to the present embodiment performs the processing flows illustrated in FIG. 7, FIG. 8, and FIG. 9 in this order.

Specifically, the processing flow illustrated in FIG. 7 illustrates a flow of exclusion process using the drawing unit exclusion history value. In addition, the processing flow illustrated in FIG. 8 illustrates a flow of exclusion process using the checking expression unit exclusion history value. In addition, the processing flow illustrated in FIG. 9 illustrates a flow of exclusion process using the individual element exclusion history value.

(Exclusion Process Using Drawing Unit Exclusion History Value)

First, the exclusion process using the drawing unit exclusion history value will be described with reference to FIG. 7.

As illustrated in FIG. 7, the selection unit 101 of the verification processing device 1 selects one of design drawings (DWG1, DWG2, . . . ) in which the drawing unit exclusion history value exceeds a predetermined threshold value (step S01). Here, this exclusion process is skipped in a case where there is no design drawing in which the drawing unit exclusion history value exceeds the predetermined threshold value.

Next, the checking unit 100 of the verification processing device 1 excludes all elements included in the one design drawing selected in step S01 from the model to be checked MOD (step S02) and performs the model re-checking (step S03).

In a case where a checking result of the model re-checking does not result in TRUE (another counterexample is output) (step S04; NO), a determination that all elements excluded in the drawing units in step S02 are not the main cause can be made. Thus, the verification processing device 1 continues further narrowing down without restoring the excluded elements to the model to be checked MOD.

On the other hand, in a case where the checking result changes to TRUE in the model re-checking (another counterexample is not output) (step S04; YES), a determination that the main cause is included in the elements excluded in the drawing units in step S02 can be made. Thus, the verification processing device 1 temporarily restores the excluded elements to the model to be checked MOD (step S05).

In a case where not all design drawings satisfying the condition in step S01 have been selected (step S06; NO), the selection unit 101 selects the next design drawing satisfying the condition (step S07). The verification processing device 1 continues narrowing down the element of the main cause by repeating the process from step S02 to step S05.

In a case where all design drawings satisfying the condition in step S01 have been selected (step S06; YES), the verification processing device 1 finishes the exclusion process using the drawing unit exclusion history value.

(Exclusion Process Using Checking Expression Unit Exclusion History Value)

Next, the exclusion process using the checking expression unit exclusion history value will be described with reference to FIG. 8.

As illustrated in FIG. 8, the selection unit 101 of the verification processing device 1 selects all elements (X1, X2, . . . ) in which the checking expression unit exclusion history value exceeds a predetermined threshold value (step S11). Here, this exclusion process is skipped in a case where there is no element in which the checking expression unit exclusion history value exceeds the predetermined threshold value.

Next, the checking unit 100 of the verification processing device 1 excludes all elements selected in step S11 from the model to be checked MOD (step S12) and performs the model re-checking (step S13).

In a case where the checking result of the model re-checking does not result in TRUE (another counterexample is output) (step S14; NO), a determination that all elements excluded in step S12 are not the main cause can be made. Thus, the verification processing device 1 continues further narrowing down without restoring the excluded elements to the model to be checked MOD.

On the other hand, in a case where the checking result changes to TRUE in the model re-checking (a counterexample is not output) (step S14; YES), a determination that the main cause is included in the elements excluded in step S12 can be made. Thus, the verification processing device 1 temporarily restores the excluded elements to the model to be checked MOD (step S15). In this case, the verification processing device 1 efficiently advances the exclusion process by further narrowing down the elements restored to the model to be checked MOD in step S15 as a target using binary search (step S16). The binary search performed in step S16 will be described later.

(Exclusion Process Using Individual Element Exclusion History Value)

Next, the exclusion process using the individual element exclusion history value will be described with reference to FIG. 9.

As illustrated in FIG. 9, the selection unit 101 of the verification processing device 1 selects all elements (X1, X2, . . . ) in which the individual element exclusion history value exceeds a predetermined threshold value (step S21). Here, this exclusion process is skipped in a case where there is no element in which the individual element exclusion history value exceeds the predetermined threshold value.

Next, the checking unit 100 of the verification processing device 1 excludes all elements selected in step S21 from the model to be checked MOD (step S22) and performs the model re-checking (step S23).

In a case where the checking result of the model re-checking does not result in TRUE (another counterexample is output) (step S24; NO), a determination that all elements excluded in step S22 are not the main cause can be made. Thus, the verification processing device 1 continues further narrowing down without restoring the excluded elements to the model to be checked MOD.

On the other hand, in a case where the checking result changes to TRUE in the model re-checking (a counterexample is not output) (step S24; YES), a determination that the main cause is included in the elements excluded in step S22 can be made. Thus, the verification processing device 1 temporarily restores the excluded elements to the model to be checked MOD (step S25). In this case, the verification processing device 1 efficiently advances the exclusion process by further narrowing down the elements restored to the model to be checked MOD in step S25 as a target using binary search (step S26). The binary search performed in step S26 will be described later.

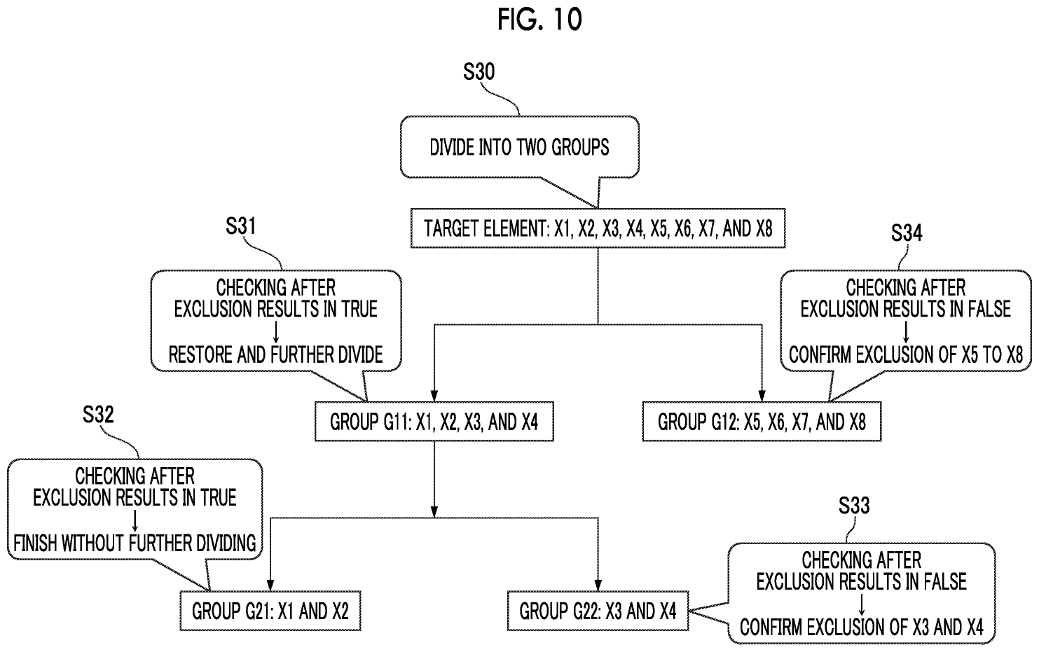

The binary search in step S16 (FIG. 8) and step S26 (FIG. 9) will be described with reference to FIG. 10.

An assumption that the elements restored to the model to be checked MOD in step S15 or step S25 are eight elements of the elements X1 to X8 is made. At this point, the selection unit 101 of the verification processing device 1 divides the elements X1 to X8 into two groups G11 (X1, X2, X3, and X4) and G12 (X5, X6, X7, and X8) (step S30).

The selection unit 101 selects any one (group G11) of the groups G11 and G12. The checking unit 100 excludes all elements X1 to X4 included in the selected group G11 from the model to be checked MOD and performs the model re-checking. Here, an assumption of checking result=TRUE (a counterexample is not output) is made. In this case, the selection unit 101 temporarily restores the elements X1 to X4 to the model to be checked MOD and further divides the elements X1 to X4 into two groups G21 (X1 and X2) and G22 (X3 and X4) (step S31).

The selection unit 101 selects any one (group G21) of the groups G21 and G22. The checking unit 100 excludes all elements X1 and X2 included in the selected group G21 from the model to be checked MOD and performs the model re-checking. Here, even in a case of checking result=TRUE (a counterexample is not output), elements constituting the group G21 are only two elements of X1 and X2. Thus, further narrowing down is not performed. The verification processing device 1 narrows down another group.

The selection unit 101 selects the other side (group G21) of the groups G21 and G22. The checking unit 100 excludes all elements X3 and X4 included in the selected group G22 from the model to be checked MOD and performs the model re-checking. Here, an assumption of checking result=FALSE (a counterexample is output) is made. In this case, a determination that the elements X3 and X4 are not the main cause can be made. Thus, the verification processing device 1 confirms the exclusion from the model to be checked MOD (step S33).

Next, the selection unit 101 selects the other side (group G12) of the groups G11 and G12. The checking unit 100 excludes all elements X5 to X8 included in the selected group G12 from the model to be checked MOD and performs the model re-checking. Here, an assumption of checking result=FALSE (a counterexample is output) is made. In this case, the selection unit 101 can determine that the elements X5 to X8 are not the main cause. Thus, the verification processing device 1 confirms the exclusion from the model to be checked MOD (step S34).

The verification processing device 1 can efficiently narrow down the main cause using the above binary search.

After the processing flows in FIG. 7 to FIG. 9 are finished, the verification processing device 1 narrows down the remaining elements one by one and completes the process of the result analysis.

(Actions and Effects)

As described above, the verification processing device 1 according to the first embodiment includes the exclusion history generation unit 102 that generates the exclusion history information indicating the exclusion frequency (exclusion history value) for each of the plurality of elements. In a case where another counterexample is output as a result of the model re-checking, the exclusion history generation unit 102 increases the exclusion history value of the selected element and updates the exclusion history information. The selection unit 101 selects an element of which the exclusion history value is relatively high based on the exclusion history information generated by the exclusion history generation unit 102 in a process of the next result analysis.

By doing so, an element that is likely to be excluded in the past result analysis is preferentially selected and excluded from the model to be checked MOD. Then, a frequency with which a step of restoring the excluded element again to the model to be checked MOD and performing the model checking again because of checking result=TRUE occurs can be reduced.

Accordingly, steps required for obtaining the result analysis from the checking result can be significantly reduced.

In addition, the exclusion history generation unit 102 according to the first embodiment generates, based on the exclusion history value for each element included in one design drawing, the exclusion history information indicating the exclusion frequency (drawing unit exclusion history value) in the design drawing units. The selection unit 101 selects all elements included in a design drawing of which the drawing unit exclusion history value is high based on the exclusion history information.

By doing so, a possibility that multiple elements can be excluded by re-checking performed once in units of functions (design drawings) less related to the occurrence of the unsafe event is increased. Accordingly, steps required for the result analysis (narrowing down the main cause) can be further reduced.

For example, defects of an air conditioning function (design drawing) generally do not include an element related to the occurrence of the unsafe event (a brake is not working, a door is open during traveling, or the like). In such a case, according to the present embodiment, a plurality of elements included in the design drawing of the air conditioning function are excluded at once, and a step leading to specification of the main cause is shortened.

In addition, the exclusion history generation unit 102 according to the first embodiment generates the exclusion history information indicating the exclusion frequency in the checking expression units (checking expression unit exclusion history value) for each of the plurality of elements. The selection unit 101 selects an element of which the checking expression unit exclusion history value corresponding to the checking expression used in the next model checking is high based on the exclusion history information.

By doing so, a possibility that multiple elements less related to the checking expression during the checking can be excluded at once is increased in a case where the number of times of the result analysis within the same checking expression is increased. Accordingly, steps required for the result analysis can be further reduced.

In addition, in a case where a counterexample is not output as a result of the model re-checking, the selection unit 101 according to the first embodiment selects one of two groups into which a plurality of previously selected elements is divided.

By doing so, the main cause can be efficiently narrowed down using the binary search.

As described above, according to the verification processing device 1 according to the first embodiment, a load required for a work of counterexample analysis in model checking can be reduced.

### Second Embodiment

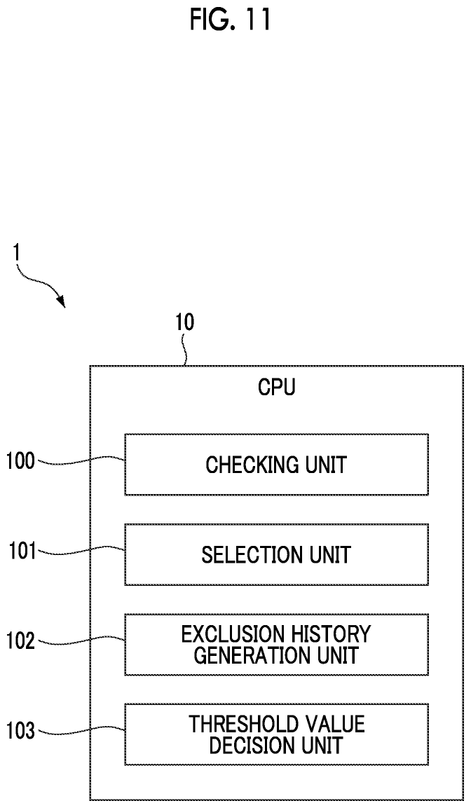

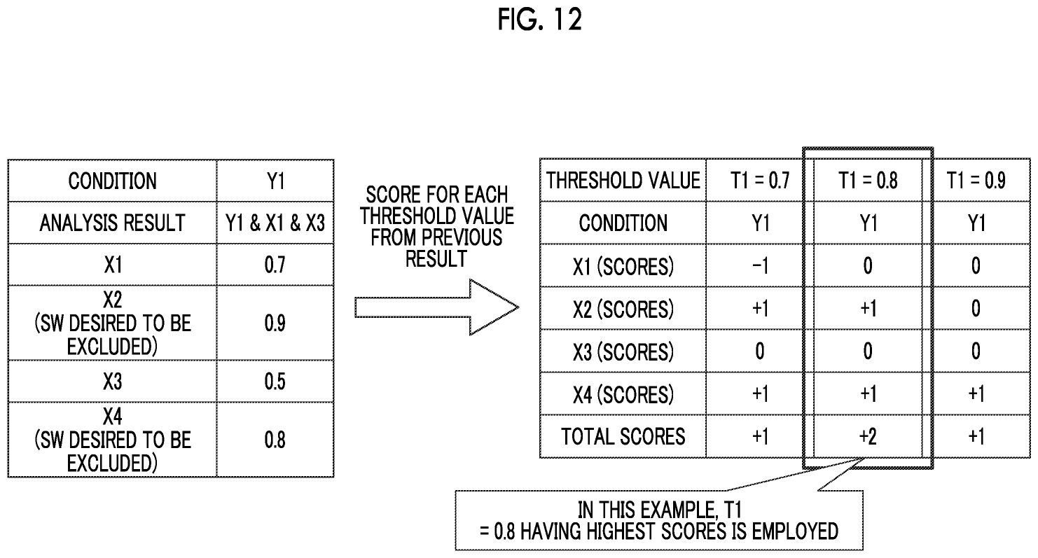

Next, the verification processing device 1 according to a second embodiment will be described with reference to FIG. 11 and FIG. 12.

(Process of Deciding Optimal Threshold Value)

FIG. 11 is a diagram illustrating a functional configuration of the CPU of the verification processing device according to the second embodiment.

As illustrated in FIG. 11, the verification processing device 1 according to the second embodiment is characterized by newly including a threshold value decision unit 103 as a function of the CPU 10.

Here, the threshold values used in step S01 in FIG. 7, step S11 in FIG. 8, and step S12 in FIG. 9 in the verification processing device 1 according to the first embodiment are fixed values. However, an optimal threshold value is decided by the function of the threshold value decision unit 103 in the verification processing device 1 according to the second embodiment.

The threshold value decision unit 103 decides the threshold value used for determining whether or not to exclude each element from the model to be checked MOD based on the exclusion frequency (exclusion history value). Particularly, the threshold value decision unit 103 decides the optimal threshold value based on the exclusion history value of an element determined as not being the main cause based on the past analysis result and the exclusion history value of an element determined as being the main cause. Hereinafter, a process of the threshold value decision unit 103 will be described in detail with reference to FIG. 12.

(Process of Threshold Value Decision Unit)

FIG. 12 is a diagram illustrating a content of the process of the threshold value decision unit according to the second embodiment.

First, the threshold value decision unit 103 has a plurality of threshold value candidates T1 (for example, “0.7”, “0.8”, and “0.9”). The threshold value decision unit 103 decides the optimal threshold value from the plurality of threshold value candidates T1 (0.7, 0.8, and 0.9) based on the analysis result in the past model checking.

For example, as in the table on the right side of FIG. 12, an assumption that the analysis result of certain model checking results in Y1 & X1 & X3, and the exclusion history values of each of the elements X1 to X4 updated by the exclusion history generation unit 102 are X1=0.7, X2=0.9, X3=0.5, and X4=0.8, respectively, is made. In this case, in a step of obtaining this analysis result (Y1 & X1 & X3) from a counterexample, it is most desirable that only the elements X2 and X4 that are not the main cause are selected at once by the selection unit 101.

Therefore, the threshold value decision unit 103 decides a threshold value with which only the elements X2 and X4 may be selected. Specifically, as in the table on the left side of FIG. 12, scoring is performed for each value of the plurality of threshold value candidates T1. Scoring rules include (A) to (D) below.

(A) In a case where an element (element that is not the main cause) to be excluded is excluded as a result of threshold value determination: +1 point

(B) In a case where an element to be excluded is not excluded as a result of threshold value determination: 0 points

(C) In a case where an element (element that is the main cause) not to be excluded is excluded as a result of threshold value determination: −1 points

(D) In a case where an element not to be excluded is not excluded as a result of threshold value determination: 0 points

The threshold value decision unit 103 decides a threshold value candidate having the highest total of the scores obtained by the rules (A) to (D) for each of the plurality of elements X1 to X4 as a threshold value to be employed in the next result analysis.

In the example illustrated in FIG. 12, the threshold value candidate “0.8” has the highest scores based on the rules (A) to (D). Accordingly, the threshold value decision unit 103 decides the threshold value to “0.8”.

(Actions and Effects)

As described above, according to the verification processing device 1 according to the second embodiment, each time the result analysis is performed, a threshold value with which only the element that is not the main cause is appropriately selected is decided from the result. Accordingly, since only the element that is not the main cause is likely to be excluded from the model to be checked MOD, steps required for the result analysis can be further reduced.

In the embodiments, processes of various processing of the verification processing device 1 are stored in a computer readable recording medium in the form of a program, and the various processes are performed by causing a computer to read and execute the program. In addition, the computer readable recording medium refers to a magnetic disk, a magneto-optical disc, a CD-ROM, a DVD-ROM, a semiconductor memory, or the like. In addition, the computer program may be distributed to the computer through a communication line, and the computer that has received the distribution may execute the program.

The program may implement a part of the above functions. Furthermore, the program may be a so-called difference file (difference program) that can implement the above functions in combination with a program already recorded in the computer system.

As described above, while several embodiments according to the present disclosure have been described, all of these embodiments are presented as an example and are not intended to limit the scope of the invention. These embodiments can be implemented in other various forms and can be subjected to various omissions, replacements, and changes without departing from the gist of the invention. These embodiments and modifications thereof fall within the invention disclosed in the claims and an equivalent scope thereof as the embodiments and the modifications fall within the scope and the gist of the invention.

### APPENDIX

For example, a verification device, a verification processing method, and a program disclosed in each embodiment are perceived as follows.

(1) The verification processing device 1 according to a first aspect includes the checking unit 100 that performs model checking on the model to be checked MOD including a plurality of elements (X1, X2, . . . ), the selection unit 101 that selects one or more of a plurality of elements included in a counterexample output as a result of the model checking, and the exclusion history generation unit 102 that generates exclusion history information indicating an exclusion frequency (exclusion history value) for each of a plurality of elements. The checking unit 100 further performs model re-checking on the model to be checked MOD obtained by excluding the selected element. In a case where another counterexample is output as a result of the model re-checking, the exclusion history generation unit 102 increases the exclusion frequency of the selected element and updates the exclusion history information. The selection unit 101 selects an element of which the exclusion frequency is high based on the exclusion history information.

(2) In the verification processing device 1 according to a second aspect, the exclusion history generation unit 102 generates, based on the exclusion frequency for each element included in one design drawing, exclusion history information indicating an exclusion frequency in design drawing units. The selection unit 101 selects all elements included in a design drawing of which the exclusion frequency in the design drawing units is high based on the exclusion history information.

(3) In the verification processing device 1 according to a third aspect, the exclusion history generation unit 102 generates exclusion history information indicating an exclusion frequency in checking expression units for each of the plurality of elements. The selection unit 101 selects an element of which the exclusion frequency in the checking expression units corresponding to a checking expression used in the next model checking is high based on the exclusion history information.

(4) In the verification processing device 1 according to a fourth aspect, in a case where a counterexample is not output as a result of the model re-checking, the selection unit 101 selects one of two groups into which a plurality of previously selected elements is divided.

(5) The verification processing device 1 according to a fifth aspect further includes the threshold value decision unit 103 that decides a threshold value used for determining whether or not to exclude each element from the model to be checked by comparing the threshold value with the exclusion frequency.

(6) A verification processing method according to a sixth aspect includes a step of performing model checking on a model to be checked including a plurality of elements, a step of selecting one or more of a plurality of elements included in a counterexample output as a result of the model checking, a step of generating exclusion history information indicating an exclusion frequency for each of a plurality of elements, a step of performing model re-checking on the model to be checked obtained by excluding the selected element, and a step of increasing, in a case where another counterexample is output as a result of the model re-checking, the exclusion frequency of the selected element and updating the exclusion history information, in which in the selecting step, an element of which the exclusion frequency is high is selected based on the exclusion history information.

(7) A program according to a seventh aspect stores a program causing a computer to execute a step of performing model checking on a model to be checked including a plurality of elements, a step of selecting one or more of a plurality of elements included in a counterexample output as a result of the model checking, a step of generating exclusion history information indicating an exclusion frequency for each of a plurality of elements, a step of performing model re-checking on the model to be checked obtained by excluding the selected element, and a step of increasing, in a case where another counterexample is output as a result of the model re-checking, the exclusion frequency of the selected element and updating the exclusion history information, in which in the selecting step, an element of which the exclusion frequency is high is selected based on the exclusion history information.

### INDUSTRIAL APPLICABILITY

According to the information processing device, the information processing method, and the program, a process related to a Mahalanobis distance can be more appropriately performed.

### REFERENCE SIGNS LIST

1: verification processing device
10: CPU
100: checking unit
101: selection unit
102: exclusion history generation unit
103: threshold value decision unit
11: memory
12: display
13: input device
14: storage
MOD: model to be checked

1. A verification processing device comprising:
a checking unit that performs model checking on a model to be checked including a plurality of elements;
a selection unit that selects one or more of a plurality of elements included in a counterexample output as a result of the model checking; and
an exclusion history generation unit that generates exclusion history information indicating an exclusion frequency for each of a plurality of elements,
wherein the checking unit further performs model re-checking on the model to be checked obtained by excluding the selected element,
in a case where another counterexample is output as a result of the model re-checking, the exclusion history generation unit increases the exclusion frequency of the selected element and updates the exclusion history information, and
the selection unit selects an element of which the exclusion frequency is high based on the exclusion history information.

2. The verification processing device according to claim 1,
wherein the exclusion history generation unit generates, based on the exclusion frequency for each element included in one design drawing, exclusion history information indicating an exclusion frequency in design drawing units, and
the selection unit selects all elements included in a design drawing of which the exclusion frequency in the design drawing units is high based on the exclusion history information.

3. The verification processing device according to claim 1,
wherein the exclusion history generation unit generates exclusion history information indicating an exclusion frequency in checking expression units for each of the plurality of elements, and
the selection unit selects an element of which the exclusion frequency in the checking expression units corresponding to a checking expression used in the next model checking is high based on the exclusion history information.

4. The verification processing device according to claim 1,
wherein in a case where a counterexample is not output as a result of the model re-checking, the selection unit selects one of two groups into which a plurality of previously selected elements is divided.

5. The verification processing device according to claim 1, further comprising:
a threshold value decision unit that decides a threshold value used for determining whether or not to exclude each element from the model to be checked by comparing the threshold value with the exclusion frequency.

6. A verification processing method comprising:
a step of performing model checking on a model to be checked including a plurality of elements;
a step of selecting one or more of a plurality of elements included in a counterexample output as a result of the model checking;
a step of generating exclusion history information indicating an exclusion frequency for each of a plurality of elements;
a step of performing model re-checking on the model to be checked obtained by excluding the selected element; and
a step of increasing, in a case where another counterexample is output as a result of the model re-checking, the exclusion frequency of the selected element and updating the exclusion history information,
wherein in the selecting step, an element of which the exclusion frequency is high is selected based on the exclusion history information.

7. A non-transitory computer readable recording medium storing a program causing a computer to execute:
a step of performing model checking on a model to be checked including a plurality of elements;
a step of selecting one or more of a plurality of elements included in a counterexample output as a result of the model checking;
a step of generating exclusion history information indicating an exclusion frequency for each of a plurality of elements;
a step of performing model re-checking on the model to be checked obtained by excluding the selected element; and
a step of increasing, in a case where another counterexample is output as a result of the model re-checking, the exclusion frequency of the selected element and updating the exclusion history information,
wherein in the selecting step, an element of which the exclusion frequency is high is selected based on the exclusion history information.
